(19) United States
(12) Patent Application Publication
(10) Pub. No.: US 2014/0054748 A1
(43) Pub. Date: Feb. 27, 2014

(54) EDGE TRIMMING METHOD FOR SEMICONDUCTOR WAFER AND SEMICONDUCTOR WAFER HAVING TRIMMED EDGE

(71) Applicant: GENMAO LIU, Singapore (SG)

(72) Inventor: GENMAO LIU, Singapore (SG)

(21) Appl. No.: 13/590,196

(22) Filed: Aug. 21, 2012

(51) Int. Cl. H01L 29/02; H01L 21/762

(52) U.S. Cl. 257/618; 438/459; 257/E21.567; 257/E29.002

(57) ABSTRACT

An edge trimming method includes providing a semiconductor wafer having a front side and a backside, trimming an edge of a periphery of the semiconductor wafer from the front side to form at least a notch region around the periphery of the front side of the semiconductor wafer, and providing the front side of the semiconductor wafer to a handle wafer. The notch region comprises a first wall and a second wall, and the first and the second wall are perpendicular to each other.

### BACKGROUND OF THE INVENTION

1. Field of the Invention

The invention relates to an edge trimming method for a semiconductor wafer and a semiconductor wafer having a trimmed edge, and more particularly, to an edge trimming method for a semiconductor wafer before wafer thinning, a semiconductor wafer having a trimmed edge for wafer thinning, and a semiconductor wafer having the trimmed edge after wafer thinning.

2. Description of the Prior Art

Wafer thinning or grinding process is required in many semiconductor device fabrications. For example, wafer thinning process is involved in back-side illuminated (BSI) manufacturing process, three-dimensional (3D) structures integrated circuits manufacturing process, etc.

Please refer to FIGS. 1-3, wherein FIG. 1 is a schematic drawing illustrating a wafer before wafer thinning, FIG. 2 is a schematic drawing illustrating the wafer after wafer thinning, and FIG. 3 is an enlarged view of a portion of the wafer after wafer thinning. As shown in FIG. 1, a wafer 10 to be thinned or grinded is bonded to a carrier wafer or a handle wafer 20. Then, the wafer 10 is thinned down from its back side by grinding as shown in FIG. 2. Please note that a portion of the wafer 10 after wafer thinning is emphasized by Circle A and enlarged as shown in FIG. 3.

Please refer to FIG. 3. It is well-known that the wafer 10 is thinned down to, exemplarily speaking, from several micrometers to several decade micrometers. Consequently, the thinned wafer, particularly speaking, the edge of the thinned wafer is always easily cracked because there is no support as shown in FIG. 3. Edge chipping 12 is a serious problem in the fabrication process because it may cause delamination, generate a large amount of particles that scratch the surface of the wafer 10, and cause wafer breakage. Unfortunately, any of the abovementioned problems reduces production yields, and therefore a method for solving the wafer edge chipping issue is always in need.

### SUMMARY OF THE INVENTION

According to a first aspect of the present invention, an edge trimming method for a semiconductor wafer is provided. The edge trimming method includes providing a semiconductor wafer having a front side and a backside, trimming an edge of a periphery of the semiconductor wafer from the front side to form at least a notch region around the periphery of the front side of the semiconductor wafer, and providing the front side of the semiconductor wafer to a handle wafer. The notch region comprises a first wall and a second wall, and the first and the second wall are perpendicular to each other.

According to a second aspect of the present invention, a semiconductor wafer having a trimmed edge is provided. The semiconductor wafer includes a backside, a front side opposite to the backside, and at least a notch region formed around a periphery of the front side of the semiconductor wafer. The notch region comprises a first wall and a second wall, and the first wall and the second wall are perpendicular to each other.

According to a third aspect of the present invention, a semiconductor wafer is provided. The semiconductor wafer includes a backside, a front side opposite to the backside, and a slanted side connecting the backside and the front side of the semiconductor wafer. The slanted side is not perpendicular to the backside and the front side of the semiconductor wafer. The slanted side and the front side further include an included angle, and the included angle is a acute angle.

According to the edge trimming method for the semiconductor wafer and the semiconductor wafer having the trimmed edge provided by the present invention, the notch region is formed around the periphery of the front side of the semiconductor before wafer thinning. Accordingly, when the wafer thinning step is performed to the backside of the semiconductor wafer, the unsupported wafer edge is completely removed and thus no edge chipping issue is resulted.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing illustrating a wafer before wafer thinning.

FIG. 2 is a schematic drawing illustrating the wafer after wafer thinning.

FIG. 3 is an enlarged view of a portion of the wafer after wafer thinning.

FIGS. 4-6 are schematic drawings illustrating an edge trimming method for a semiconductor wafer provided by a first preferred embodiment of the present invention, wherein

FIG. 5 is a schematic drawing in a step subsequent to FIGS. 4, and

FIG. 6 is a schematic drawing in a step subsequent to FIG. 5.

FIGS. 7-10 are schematic drawings illustrating an edge trimming method for a semiconductor wafer provided by a second preferred embodiment of the present invention, wherein

FIG. 8 is a schematic drawing in a step subsequent to FIG. 7,

FIG. 9 is a schematic drawing in a step subsequent to FIG. 8, and

FIG. 10 is a schematic drawing in a step subsequent to FIG. 9.

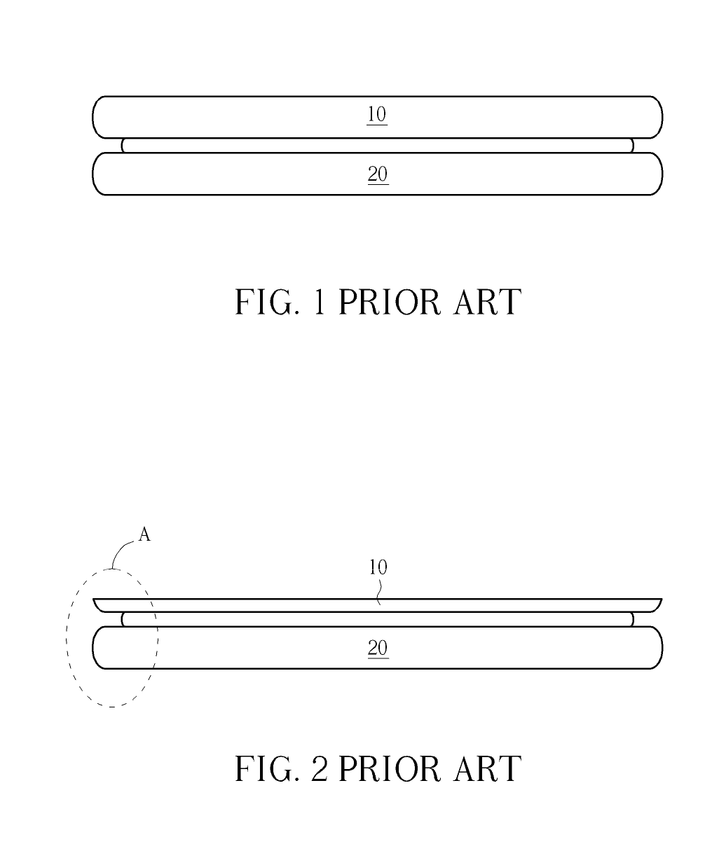

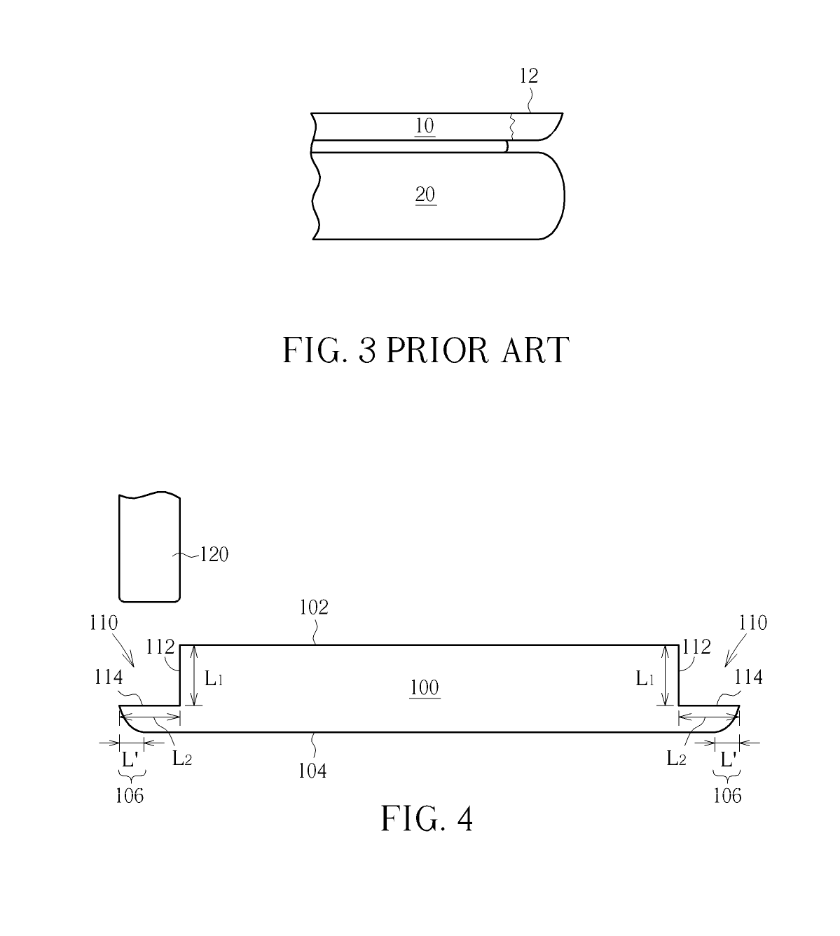

### DETAILED DESCRIPTION

Please refer to FIGS. 4-6, which are schematic drawings illustrating an edge trimming method for a semiconductor wafer provided by a first preferred embodiment of the present invention. As shown in FIG. 4, a semiconductor wafer 100 having a front side 102 and a backside 104 is provided. The front side 102 and the back side 104 are opposite to each other. The semiconductor wafer 100 can be a device wafer having a plurality of semiconductor devices (not shown) formed in the front side 102. Furthermore, it is well-known to those skilled in the art that the semiconductor wafer 100 includes a bevel region 106 around a periphery of the semiconductor wafer 100. As shown in FIG. 4, the bevel region 106 includes a cambered surface connecting the front side 102 and the backside 104. Additionally, the bevel region 106 includes a length L′, and the length L′ is parallel with both sides of the semiconductor wafer 100.

Please still refer to FIG. 4. Subsequently, a wheel, for example but not limited to a diamond wheel 120, is provided to trim an edge of periphery of the semiconductor wafer 100 from the front side 102. A trimming direction is perpendicular to both sides of the semiconductor wafer 100. Furthermore, the wheel 120 is perpendicular to the front side 102 and the backside 104 of the semiconductor wafer 100 as shown in FIG. 4. Accordingly, a notch region 110 around the periphery of the front side 102 of the semiconductor wafer 100 is formed. It is noteworthy that the periphery of the front side 102 of the wafer 100 can be entirely or partially trimmed. Accordingly, the notch region 110 can be a continuous ring region formed around the entire periphery of the front side 102 of the semiconductor wafer 100, and thus a diameter of the front side 102 is smaller than a diameter of the back side 104. OR, the notch region 110 can be a non-continuous region formed in portions of the periphery and is interrupted by the front side 102.

Please still refer to FIG. 4. The notch region 110 includes a first wall 112 and a second wall 114, and the first wall 112 and the second wall 114 are perpendicular to each other. According to the preferred embodiment, the first wall 112 is perpendicular to the front side 102 and the backside 104 of the semiconductor wafer 100 while the second wall 114 is parallel with the front side 102 and the backside 104 of the semiconductor wafer 100 as shown in FIG. 4. The second wall 114 of the notch region 110 includes a second length L₂, and the second length L₂ is larger than the length L′ of the bevel region 106 as shown in FIG. 4. It should be noted that though the second length L₂ is larger than the length L′ of the bevel region 106, there is a principle that the semiconductor wafer 100 suffers no device loss after trimming by the wheel.

Please refer to FIG. 5. Subsequently, the semiconductor wafer 100 is flipped over and the front side 102 of the semiconductor wafer 100 is bonded to a handle wafer 130 by an adhesive material 132. It is observed that portions of the semiconductor wafer 100 above the second wall 114 are not supported by the handle wafer 130 and hang in the air as shown in FIG. 5.

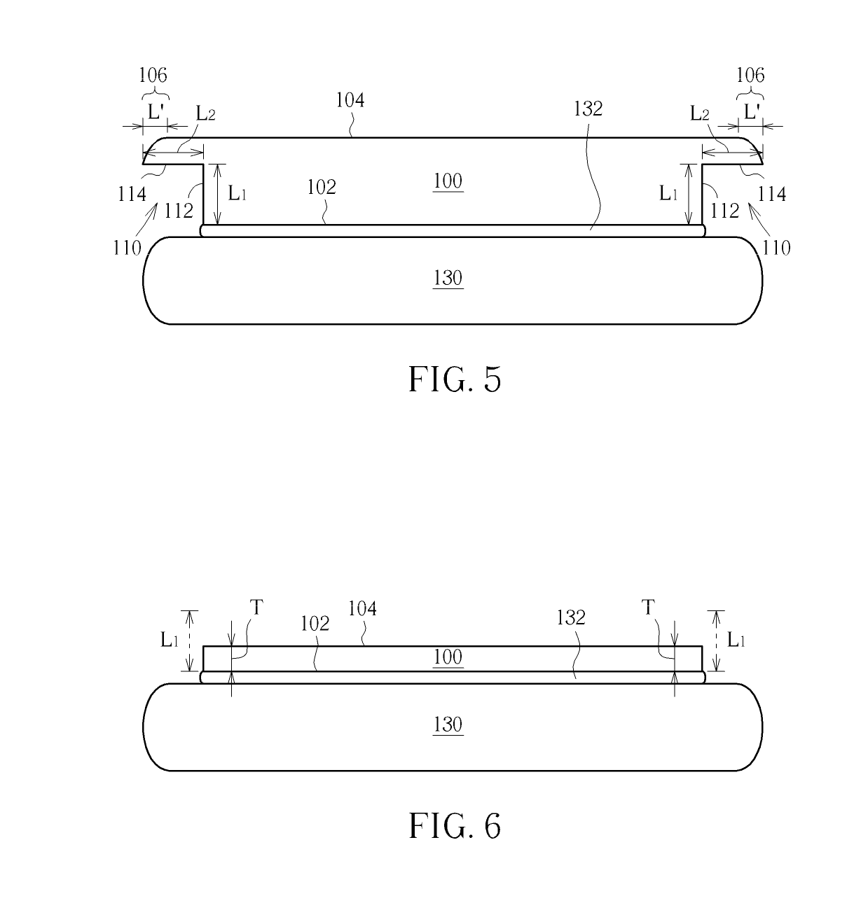

Please refer to FIG. 6. Then, a wafer thinning step is performed to the backside 104 of the semiconductor wafer 100 so that the semiconductor wafer 100 obtains a predetermined thickness T as expected after the wafer thinning step as shown in FIG. 6. It is noteworthy that during the wafer thinning step, the bevel region 106, the notch region 110, and the portions of the semiconductor wafer 100 that are not supported by the handle wafer 130 are eliminated. Additionally, to ensure the elimination of the unsupported portions, the first length Li of the first wall 112 (emphasized as the dotted line shown in FIG. 6) is larger than the predetermined thickness T of the semiconductor wafer 100, which is obtained by the wafer thinning step. Preferably, the first length L₁ is 2 to 4 times to the predetermined thickness T of the semiconductor wafer 100 after the thinning step. For example, when the predetermined thickness T of the semiconductor wafer 100 is 10-40 micrometers (pm), the notch region 110 is formed to have the first wall 112 with the first length L₁ of about 150 μm, but not limited to this. It is conceivable that the first length L₁ of the first wall 110 is modifiable depending on the predetermined thickness T of the semiconductor wafer 100 after the wafer thinning step.

According to the edge trimming method the semiconductor wafer provided by the first preferred embodiment, the notch region 110 is formed on the periphery of the front side 102 of the semiconductor wafer 100 before the wafer thinning step. Therefore, portions of the semiconductor wafer 100 that are not supported by the handle wafer 130 are eliminated as shown in FIG. 6 and the edge chipping issue is completely solved.

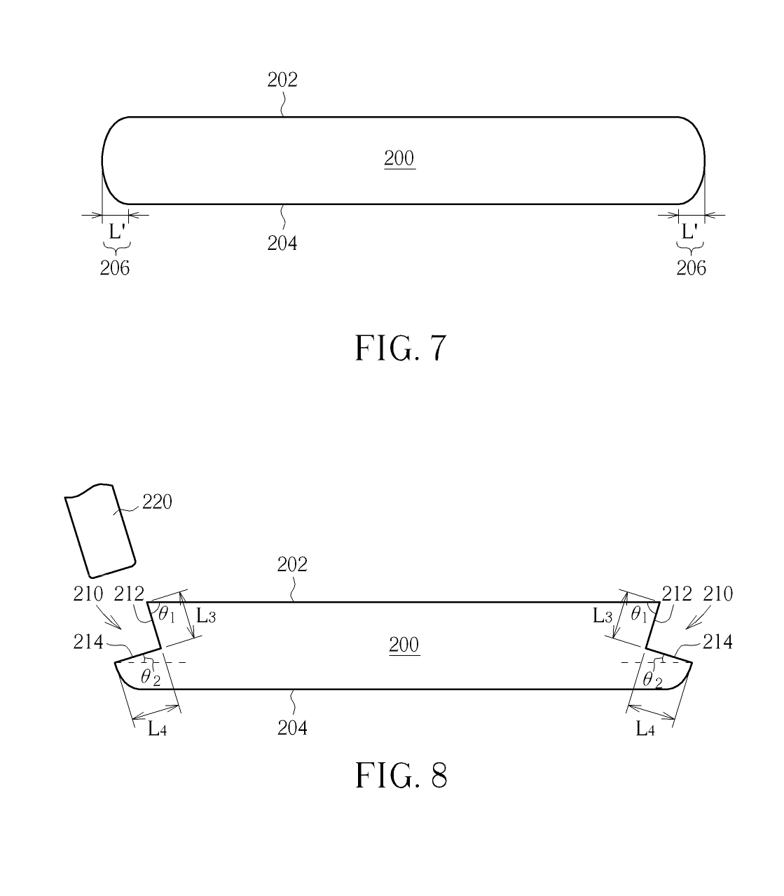

Please refer to FIGS. 7-10, which are schematic drawings illustrating an edge trimming method for a semiconductor wafer provided by a second preferred embodiment of the present invention. As shown in FIG. 7, a semiconductor wafer 200 having a front side 202 and a backside 204 is provided. The front side 202 and the back side 204 are opposite to each other. As mentioned above, the semiconductor wafer 200 includes a bevel region 206 around a periphery of the semiconductor wafer 200. As shown in FIG. 7, the bevel region 206 includes a cambered surface connecting the front side 202 and the backside 204. Additionally, the bevel region 206 includes a length L′.

Please refer to FIG. 8. Subsequently, a wheel 220 is provided to trim an edge of periphery of the semiconductor wafer 200 from the front side 202. As mentioned above, a trimming direction is perpendicular to both sides of the semiconductor wafer 200. It is noteworthy that according to the second preferred embodiment, the wheel 220 is not perpendicular to the front side 202 and the backside 204 of the semiconductor wafer 200 as shown in FIG. 8. Accordingly, a notch region 210 around the periphery of the front side 202 of the semiconductor wafer 200 is formed. As mentioned above, the periphery of the front side 202 of the wafer 200 can be trimmed entirely or partially. Therefore, the notch region 210 can be a continuous ring region formed around the entire periphery of the front side 202 of the semiconductor wafer 200, and thus a diameter of the front side 202 is smaller than a diameter of the back side 204. OR, the notch region 210 can be a non-continuous region formed in portions of the periphery and is interrupted by the front side 202.

Please still refer to FIG. 8. The notch region 210 includes a first wall 212 and a second wall 214, and the first wall 212 and the second wall 214 are perpendicular to each other. According to the preferred embodiment, the first wall 212 and the front side 202 have an included angle θ₁, and the included angle θ₁ is smaller than 90 degrees (°). In other words, the first wall 212 is not perpendicular to the front side 202 and the backside 204 of the semiconductor wafer 200. Furthermore, the second wall 214 and the backside 204 have an included angle θ₂, and included angle θ₂ is larger than 0°. In other words, the second wall 214 is not parallel with the front side 202 and the backside 204 of the semiconductor wafer 200. The first wall 212 of the notch region 210 includes a first length L₃. The second wall 214 of the notch region 210 includes a second length L₄, and the second length L₄ is larger than the length L′ of the bevel region 206. As mentioned above, there is a principle that the semiconductor wafer 200 suffers no device loss after trimming by the wheel 220.

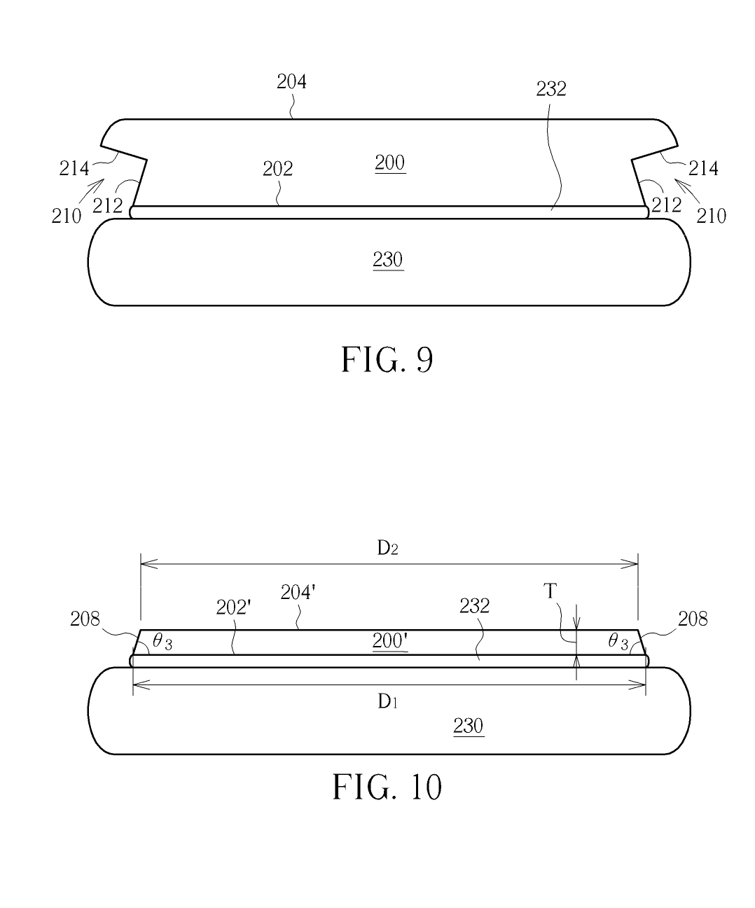

Please refer to FIG. 9. Subsequently, the semiconductor wafer 200 is flipped over and the front side 202 is bonded to a handle wafer 230 by an adhesive material 232. It is observed that portions of the semiconductor wafer 200 are not supported by the handle wafer 230 and hang in the air as shown in FIG. 9.

Please refer to FIG. 10. Then, a wafer thinning step is performed to the backside 204 of the semiconductor wafer 200 so that the semiconductor wafer 200 obtains a predetermined thickness T as expected after the wafer thinning step as shown in FIG. 10. It is noteworthy that during the wafer thinning step, the notch region 210 and the portions of the semiconductor wafer 200 that are not supported by the handle wafer 230 are eliminated. Additionally, to ensure the elimination of the unsupported portions, the first length L₃ of the first wall 212 is larger than the predetermined thickness T of the semiconductor wafer 200 after the wafer thinning step. Preferably, the first length L₃ is 2 to 4 times to the thickness T of the semiconductor wafer 200 after the thinning step. For example, when the predetermined thickness T of the semiconductor wafer 200 after the wafer thinning step is 10-40 μm, the notch region 210 is formed to have the first wall 212 with the first length L₃ of about 150 μm, but not limited to this. It is conceivable that the first length L₃ of the first wall 210 is modifiable depending on the predetermined thickness T of the semiconductor wafer 200 after the wafer thinning step.

Please refer to FIG. 10. After the wafer thinning process, a thinned semiconductor wafer 200′ is obtained. The thinned semiconductor wafer 200′ includes a backside 204′ and a front side 202 opposite to the backside 204′, and a slanted side 208 connecting the backside 204′ and the front side 202. It should be noted that the slanted side 208 is not perpendicular to both of the backside 204′ and the front side 202 as shown in FIG. 10. Particularly speaking, the slanted side 208 and the front side 202 have an included angle θ₃ and the included angle θ₃ is an acute angle. Accordingly, a cross-sectional view of the thinned semiconductor wafer 200′ shows that the thinned semiconductor wafer 200′ includes a trapezoid shape as shown in FIG. 10. And a diameter D₁ diameter of the front side 202 of the thinned semiconductor wafer 200′ is larger than a diameter of the backside 204′ of the thinned semiconductor wafer 200′.

According to the edge trimming method the semiconductor wafer provided by the second preferred embodiment, the notch region 210 is formed on the periphery of the front side 202 of the semiconductor wafer 200 before the wafer thinning step. Therefore, portions of the semiconductor wafer 200 that are not supported by the handle wafer 230 are eliminated as shown in FIG. 10 and the edge chipping issue is completely solved.

According to the edge trimming method for the semiconductor wafer and the semiconductor wafer having the trimmed edge provided by the present invention, the notch region is formed around the periphery of the front side of the semiconductor before wafer thinning. Accordingly, when the wafer thinning step is performed to the backside of the semiconductor wafer, the unsupported wafer edge is completely removed and thus no edge chipping issue is resulted.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An edge trimming method for a semiconductor wafer comprising:
providing a semiconductor wafer having a front side and a backside;
trimming an edge of a periphery of the semiconductor wafer from the front side to form at least a notch region around the periphery of the front side of the semiconductor wafer; and
providing the front side of the semiconductor wafer to a handle wafer; wherein the notch region comprises a first wall and a second wall, and the first and the second wall are perpendicular to each other.

2. The edge trimming method for the semiconductor wafer according to claim 1, wherein the first wall is perpendicular to the front side and the backside of the semiconductor wafer.

3. The edge trimming method for the semiconductor wafer according to claim 2, wherein the second wall is parallel with the front side and the backside of the semiconductor wafer.

4. The edge trimming method for the semiconductor wafer according to claim 1, wherein the first wall and the front side of the semiconductor wafer comprise a first included angle and the first included angle is smaller than 90 degrees.

5. The edge trimming method for the semiconductor wafer according to claim 4, wherein the second wall and the backside of the semiconductor wafer comprise a second included angle and the second included angle is larger than 0 degree.

6. The edge trimming method for the semiconductor wafer according to claim 1, further comprising performing a thinning step to the backside of the semiconductor wafer.

7. The edge trimming method for the semiconductor wafer according to claim 6, wherein the semiconductor wafer after the thinning step comprises a predetermined thickness.

8. The edge trimming method for the semiconductor wafer according to claim 7, wherein the first wall comprises a first length and the first length is larger than the predetermined thickness of the semiconductor wafer after thinning step.

9. The edge trimming method for the semiconductor wafer according to claim 8, wherein the first length is 2 to 4 times to the predetermined thickness of the semiconductor wafer after the thinning step.

10. The edge trimming method for the semiconductor wafer according to claim 8, wherein the second wall comprises a second length, the semiconductor wafer further comprises a bevel region, and the bevel region comprises a third length.

11. The edge trimming method for the semiconductor wafer according to claim 10, wherein the third length is smaller than the second region.

12. A semiconductor wafer having a trimmed edge, comprising:
a backside;
a front side opposite to the backside; and
at least a notch region formed around a periphery of the front side of the semiconductor wafer; wherein the notch region comprises a first wall and a second wall, and the first wall and the second wall are perpendicular to each other.

13. The semiconductor wafer having the trimmed edge according to claim 12, wherein the first wall is perpendicular to the backside and the front side of the semiconductor wafer.

14. The semiconductor wafer having the trimmed edge according to claim 13, wherein the second wall is parallel with the backside and the front side of the semiconductor wafer.

15. The semiconductor wafer having the trimmed edge according to claim 12, wherein the first wall and the front side of the semiconductor wafer comprise a first included angle and the first included angle is smaller than 90 degrees.

16. The semiconductor wafer having the trimmed edge according to claim 15, wherein the second wall and the backside of the semiconductor wafer comprise a second included angle and the second included angle is larger than 0 degree.

17. The semiconductor wafer having the trimmed edge according to claim 12 wherein the second wall comprises a second length, the semiconductor wafer further comprises a bevel region, the bevel region comprises a third length, and the third length is smaller than the second region.

18. A semiconductor wafer comprising:
a backside;
a front side opposite to the backside; and
a slanted side connecting the backside and the front side of the semiconductor wafer; wherein the slanted side is not perpendicular to the backside and the front side of the semiconductor wafer, the slanted side and the front side comprise an included angle and the included angle is an acute angle.

19. The semiconductor wafer according to claim 18, wherein a diameter of the front side of the semiconductor wafer is larger than a diameter of the backside of the semiconductor wafer.
